(19) United States
(12) Patent Application Publication
(10) Pub. No.: US 2025/0207294 A1
(43) Pub. Date: Jun. 26, 2025

(54) MANUFACTURING METHOD OF SILICON SINGLE CRYSTAL

(71) Applicant: SUMCO Corporation, Tokyo (JP)

(72) Inventors: Keisuke HIIDOME, Tokyo (JP); Daichi YAGI, Tokyo (JP); Takahiro KANEHARA, Tokyo (JP); Norihito FUKATSU, Tokyo (JP)

(73) Assignee: SUMCO Corporation, Tokyo (JP)

(21) Appl. No.: 18/846,919

(22) PCT Filed: Jan. 12, 2023
(86) PCT No.: PCT/JP2023/000532

§ 371 Date: Sep. 13, 2024

(30) Foreign Application Priority Data
Mar. 15, 2022 (JP) 2022-040339

(51) Int. Cl. C30B 15/04; C30B 15/20; C30B 29/06

(52) U.S. Cl. CPC C30B 15/04; C30B 15/20; C30B 29/06

(57) ABSTRACT

A manufacturing method of a silicon single crystal includes a melting step of producing a silicon melt containing a main-dopant in a pulling furnace and a crystal pulling step of pulling a silicon single crystal from the silicon melt while feeding Ar gas into the pulling furnace. The crystal pulling step includes at least one additional doping step of charging a sub-dopant to the silicon melt. The additional doping step controls a flow velocity F₂ of the Ar gas passing through a gap between a lower end of a heat-shield body installed above the silicon melt and a liquid surface of the silicon melt to 0.75 m/s to 1.1 m/s.

### TECHNICAL FIELD

The present invention relates to a manufacturing method of a silicon single crystal using a Czochralski method (CZ method) and, more particularly to a method for additionally feeding a dopant in the middle of a crystal pulling process.

### BACKGROUND ART

Most silicon single crystals used for a substrate material of semiconductor devices are manufactured by the CZ method. In the CZ method, a seed crystal is dipped into a silicon melt stored in a quartz crucible, and then the seed crystal is gradually lifted while the seed crystal and quartz crucible are being rotated, whereby a large-diameter single crystal is grown below the seed crystal. Using the CZ method allows high-quality silicon single e crystals to be manufactured at a high yield.

In the growth of the silicon single crystal, various dopants are used to adjust electrical resistivity (hereinafter, referred to merely as “resistivity”) of the single crystal. Typical examples of dopants include boron (B), phosphorus (P), arsenic (As), and antimony (Sb). The dopant is typically charged to a quartz crucible together with a polycrystalline silicon raw material and melted by heating together therewith, whereby a silicon melt containing a predetermined amount of dopant is produced.

However, the dopant concentration in the silicon single crystal changes in the pulling direction due to segregation, so that it is difficult to achieve a uniform resistivity in the silicon single crystal pulling direction. To solve this, a method of feeding a dopant in the middle of the silicon single crystal pulling is effective. For example, a p-type dopant is added to the silicon melt in the middle of the pulling of ann-type silicon single crystal. This can prevent a decrease in the resistivity of the silicon single crystal due to segregation of an n-type dopant. To charge a dopant in the middle of the pulling is referred to as “additional doping”. In particular, a method of additionally feeding a sub-dopant having a conductivity type opposite to that of a main-dopant is referred to as “counter-doping”.

Regarding the counter-doping technique, Patent Document 1 describes that a dopant is added such that the feeding rate of a dopant having a conductivity type (e.g., p-type) opposite to that (e.g., n-type) of a dopant that has been previously fed satisfies a predetermined relational expression. Further, Patent Document 2 describes that a rod-like silicon crystal containing a sub-dopant is inserted into a raw material melt to thereby control the axial resistivity of a silicon single crystal to be grown.

### BACKGROUND ART LITERATURE

### Patent Literature

Patent Literature 1: Japanese Patent Laid-open Publication No. H03-247585A
Patent Literature 2: Japanese Patent Laid-open Publication No. 2016-216306A

### SUMMARY OF THE INVENTION

### Problems to be Solved by the Invention

However, in the counter-doping in which a granular dopant is fed into a silicon melt stored in a quartz crucible, there is a problem that the solid dopant is taken into the single crystal through a solid-liquid interface between the silicon melt and the single crystal before being completely dissolved in the melt, resulting in dislocation of the silicon single crystal. Such a problem can occur not only when a sub-dopant having a conductivity type opposite to that of a main-dopant is fed but also when a sub-dopant having the same conductivity type as that of a main-dopant is additionally fed.

An object of the present invention is therefore to provide a manufacturing method of a silicon single crystal capable of preventing dislocation of the single crystal in the additional doping step in which the solid sub-dopant is charged in the middle of crystal pulling.

### Means for Solving the Problems

To solve the above problem, a manufacturing method of a silicon single crystal according to the present invention includes: a melting step of producing a silicon melt containing a main-dopant in a pulling furnace; and a crystal pulling step of pulling a silicon single crystal from the silicon melt while feeding Ar gas into the pulling furnace. The crystal pulling step includes at least one additional doping step of charging a sub-dopant to the silicon melt, and the additional doping step regulates a flow velocity of the Ar gas passing through a gap between a lower end of a heat-shield body installed above the silicon melt so as to surround the silicon single crystal pulled from the silicon melt and a liquid surface of the silicon melt to 0.75 m/s to 1.1 m/s.

According to the present invention, it is possible to prevent dislocation of the silicon single crystal caused when the sub-dopant is taken into the silicon melt after reaching the solid-liquid interface in an unmelted state.

In the present invention, a width of the gap is preferably controlled to 50 mm to 90 mm in the crystal pulling step. When the gap between the heat-shield body and the melt surface is thus relatively large, the sub-dopant charged to the silicon melt is easily taken into the silicon single crystal, making dislocation of the silicon single crystal more likely to occur. However, in the present invention, the flow velocity of the Ar gas passing through the gap and flowing in the vicinity of the melt surface is regulated to 0.75 m/s to 1.1 m/s, so that dislocation of the silicon single crystal can be prevented.

In the present invention, the additional doping step preferably regulates the flow velocity of the Ar gas by controlling at least one of the flow rate of the Ar gas to be fed into the pulling furnace and an internal pressure of the pulling furnace. Through such control, the flow velocity of the Ar gas flowing in the vicinity of the silicon melt surface can be regulated to 0.75 m/s to 1.1 m/s.

In the present invention, the additional doping step preferably controls an internal pressure of the pulling furnace to 10 Torr to 30 Torr. When the in-furnace pressure is higher than 30 Torr, the flow velocity of the Ar gas in the vicinity of the silicon melt surface decreases, thus making dislocation of the silicon single crystal more likely to occur. However, according to the present invention, the in-furnace pressure is controlled to 10 Torr to 30 Torr, so that it is possible to prevent the flow velocity of the Ar gas in the vicinity of the silicon melt surface from decreasing. Therefore, the probability that the dopant charged to the silicon melt is taken into the solid-liquid interface in an unmelted state can be reduced.

In the present invention, the crystal pulling step preferably returns the flow velocity of the Ar gas after completion of the additional doping step to the flow velocity of the Ar gas before the start of the additional doping step. This allows crystal pulling to be continued under Ar gas supply conditions suitable for crystal pulling and desired crystal quality to be maintained while preventing dislocation of the single crystal during additional doping.

### Effects of the Invention

According to the present invention, it is possible to provide a manufacturing method of a silicon single crystal capable of preventing dislocation of the single crystal in the additional doping step in which the solid sub-dopant is charged in the middle of crystal pulling.

### BRIEF DESCRIPTION OF THE DRAWINGS

FIG. 1 is a schematic cross-sectional view schematically illustrating a configuration of a single crystal manufacturing apparatus according to an embodiment of the present invention.

FIG. 2 is a flowchart for explaining a manufacturing method of a silicon single crystal according to an embodiment of the present invention.

FIG. 3 is a flowchart for explaining the straight body growing step including the counter-doping step (additional doping step).

FIG. 4 is a view for explaining a method of calculating the Ar flow velocity.

FIG. 5 is a graph illustrating the relation between the dopant charging period and Ar flow velocity.

FIG. 6 is a graph illustrating a change in resistivity in the silicon single crystal when the counter-doping is performed two times.

### MODE FOR CARRYING OUT THE INVENTION

Hereinafter, a preferred embodiment of the present invention will be described in detail with reference to the accompanying drawings.

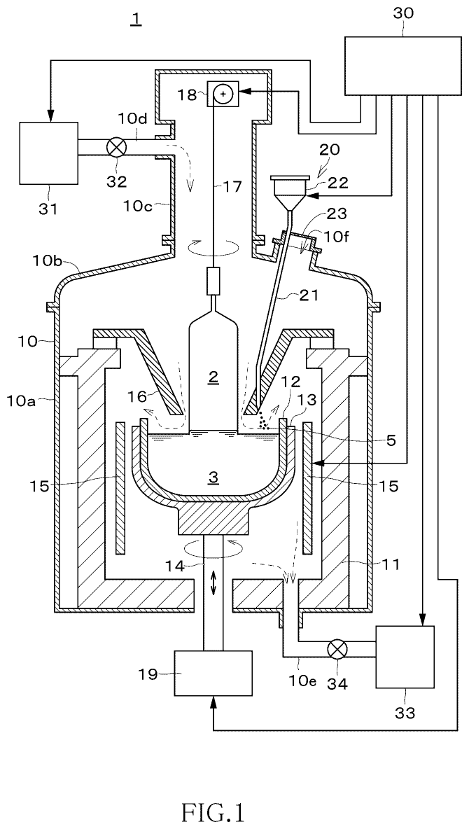

FIG. 1 is a schematic cross-sectional view schematically illustrating a configuration of a single crystal manufacturing apparatus according to an embodiment of the present invention.

As illustrated in FIG. 1, a single crystal manufacturing apparatus 1 includes a chamber 10 constituting a pulling furnace for a silicon single crystal 2, a quartz crucible 12 disposed in the chamber 10, a graphite susceptor 13 supporting the quartz crucible 12, a shaft 14 rotatably and vertically movably supporting the susceptor 13, a heater 15 disposed around the susceptor 13, a heat-shield body 16 disposed above the quartz crucible 12, a single crystal pulling wire 17 disposed above the quartz crucible 12 so as to be coaxial with the shaft 14, a wire winding mechanism 18 disposed at the upper portion of the chamber 10, a dopant feeding device 20 for feeding a dopant raw material 5 into the quartz crucible 12, and a controller 30 for controlling the above components.

The chamber 10 is constituted of a main chamber 10a, a top chamber 10b covering the upper opening of the main chamber 10a, and an elongated cylindrical pull chamber 10c connected to the upper opening of the top chamber 10b. The quartz crucible 12, susceptor 13, heater 15, and heat-shield body 16 are provided inside the main chamber 10a. The susceptor 13 is fixed to the upper end portion of the shaft 14 which is vertically extending so as to penetrate the bottom center of the chamber 10, and the shaft 13 is vertically moved and rotated by a shaft drive mechanism 19.

The heater 15 is used to melt a polycrystalline silicon raw material filled in the quartz crucible 12 to produce a silicon melt 3. The heater 15 is a resistance heating type heater made of carbon and is provided so as to surround the quartz crucible 12 in the susceptor 13. The heater 15 is surrounded by a heat insulating material 11. The heat insulating material 11 is located along the inner wall surface of the main chamber 10a, whereby heat retention performance inside the main chamber 10a can be enhanced.

The heat-shield body 16 is provided for preventing the silicon single crystal 2 from being heated by radiation heat from the heater 15 and quartz crucible 12 and suppressing a temperature variation of the silicon melt 3. The heat-shield body 16 is a substantially cylindrical member whose diameter is reduced downward from above and provided so as to cover the silicon melt 3 from above and to surround the silicon single crystal 2 being grown. The heat-shield body 16 is preferably made of graphite. The heat-shield body 16 has, at its center, an opening larger than the diameter of the silicon single crystal 2 to thereby provide a pulling path for the silicon single crystal 2. The silicon single crystal 2 is pulled upward through the opening, as illustrated. The opening diameter of the heat-shield body 16 is smaller than the aperture of the quartz crucible 12. The lower end portion of the heat-shield body 16 is positioned inside the quartz crucible 12, so that even when the rim upper end of the quartz crucible 12 is lifted exceeding the lower end of the heat-shield body 16, the heat-shield body 16 does not interfere with the quartz crucible 12.

The amount of melt in the quartz crucible 12 decreases with the growth of the silicon single crystal 2; however, by controlling lift of the quartz crucible 12 so as to keep the distance (gap value or gap width) between the melt surface and the lower end of the heat-shield body 16 constant, it is possible to suppress a temperature variation of the silicon melt 3 and to make the flow velocity of Ar gas flowing in the vicinity of the melt surface (purge gas induction path) constant, thereby controlling the evaporation amount of a dopant from the silicon melt 3. Thus, stability of crystal defect distribution, oxygen concentration distribution, resistivity distribution, etc., in the pulling axis direction of the single crystal can be improved.

A wire 17 serving as the pulling shaft for the silicon single crystal 2 and the wire winding mechanism 18 for winding the wire 17 are provided above the quartz crucible 12. The wire winding mechanism 18 has a function of rotating the silicon single crystal 2 with the wire 17. The wire winding mechanism 18 is provided at the upper portion of the pull chamber 10c. The wire 17 extends downward from the wire winding mechanism 18, passing through the pull chamber 10c until the leading end thereof reaches the inner space of the main chamber 10a. FIG. 1 illustrates a state where the silicon single crystal 2 being grown is suspended by the wire 17. Upon pulling of the silicon single crystal, the seed crystal is dipped into the silicon melt 3, and the wire 17 is gradually pulled up while the quartz crucible 12 and seed crystal are being rotated to grow the silicon single crystal.

A gas inlet port 10d for introducing Ar gas (purge gas) into the chamber 10 is formed at the upper portion of the pull chamber 10c, and a gas exhaust port 10e for exhausting the Ar gas from the chamber 10 is formed at the bottom of the main chamber 10a. The Ar gas mentioned here refers to a gas whose main component (more than 50 vol. %) is argon and may contain hydrogen or nitrogen gas.

An Ar gas supply source 31 is connected to the gas inlet port 10d through a mass flow controller 32. The Ar gas from the Ar gas supply source 31 is introduced into the chamber 10 from the gas inlet port 10d, and the introduction amount thereof is controlled by the mass flow controller 32. The AR gas in the sealed chamber 10 is exhausted outside the chamber 10 through the gas exhaust port 10e, so that it is possible to collect SiO gas or CO gas generated in the chamber 10 to thereby keep the inside of the chamber 10 clean. The Ar gas flowing from the gas inlet port 10d toward the gas exhaust port 10e passes through the opening of the heat-shield body 16, then flows from the center portion of the pulling furnace along the melt surface, and descends to reach the gas exhaust port 10e.

A vacuum pump 33 is connected to the gas exhaust port 10e through piping, and a valve 34 is used to control the flow rate of the Ar gas while the vacuum pump 33 sucks the Ar gas in the chamber 10 to thereby maintain the inside of the chamber 10 in a certain depressurized state. The air pressure in the chamber 10 is measured by a pressure gauge, and the amount of the Ar gas exhausted from the gas exhaust port 10e is controlled so as to make the air pressure in the chamber 10 constant.

The dopant feeding device 20 includes a dopant feeding tube 21 drawn inside the chamber 10 from the outside thereof, a dopant hopper 22 installed outside the chamber 10 so as to be connected to the upper end of the dopant feeding tube 21, and a seal cap 23 for sealing an opening 10f of the top chamber 10b through which the dopant feeding tube 21 penetrates.

The dopant feeding tube 21 extends from the installation position of the dopant hopper 22, passes through the opening 10f of the top chamber 10b, and reaches immediately above the silicon melt 3 in the quartz crucible 12. In the middle of the pulling of the silicon single crystal 2, the dopant raw material 5 is additionally fed from the dopant feeding device 20 to the silicon melt 3 in the quartz crucible 12. The dopant raw material 5 discharged from the dopant hopper 22 is fed to the silicon melt 3 through the dopant feeding tube 21.

The dopant raw material 5 fed from the dopant feeding device 20 is granular silicon containing a sub-dopant. Such a dopant raw material 5 is produced by growing a silicon crystal containing the sub-dopant at a high concentration using, for example, a CZ method, and then finely crushing the grown silicon crystal. However, the dopant raw material 5 used for the counter-doping is not limited to silicon containing the sub-dopant and may be a simple substance of the dopant or a compound containing a dopant atom. Further, the shape of the dopant raw material 5 is not limited to the granular shape, and may be a plate shape or a rod shape.

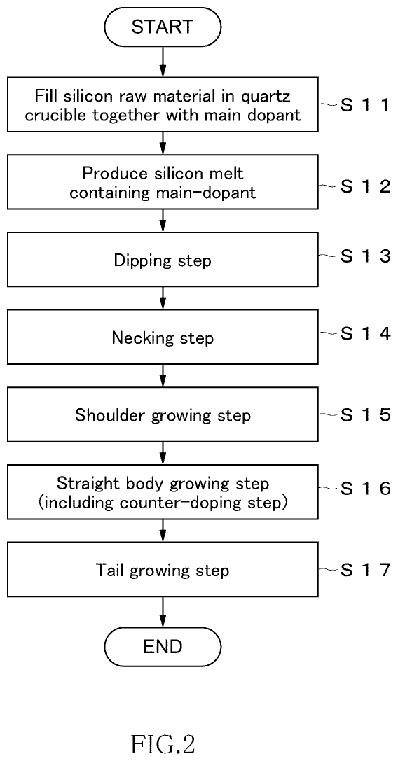

FIG. 2 is a flowchart for explaining a manufacturing method of a silicon single crystal according to an embodiment of the present invention.

As illustrated in FIG. 2, in the manufacturing of the silicon single crystal 2, a polycrystalline silicon material is filled in the quartz crucible 12 together with a main-dopant (material filling step S11). The main-dopant when an n-type silicon single crystal is pulled up is, for example, phosphorus (P), arsenic (As), or antimony (Sb), and the main-dopant when a p-type silicon single crystal is pulled up is, for example, boron (B), aluminum (Al), gallium (Ga), or indium (In). Subsequently, the polycrystalline silicon in the quartz crucible 12 is melted in heat generated by the heater 15 to produce the silicon melt 3 containing the main-dopant (melting step S12).

Then, the seed crystal attached to the leading end portion of the wire 17 is lowered to be dipped into the silicon melt 3 (step S13). After that, a crystal pulling step (steps S14 to S17) is performed, in which the seed crystal is gradually pulled up while being in contact with the silicon melt 3 to grow the single crystal.

In the crystal pulling step, a necking step S14 of forming a neck whose crystal diameter is narrowed for non-dislocation, a shoulder growing step S15 of forming a shoulder whose crystal diameter is gradually increased, a straight body growing step S16 of forming a straight body whose crystal diameter is maintained at a prescribed diameter (e.g., 300 mm), and a tail growing step S17 of forming a tail whose crystal diameter is gradually decreased are sequentially performed. Finally, the single crystal is separated from the melt surface. Through the above steps, a silicon single crystal ingot is completed.

The straight body growing step S16 preferably includes at least one counter-doping step (additional doping step) of charging a sub-dopant having a conductivity type opposite to that of a main-dopant contained in the silicon single crystal 2. This can suppress a change in the resistivity of the straight body of the silicon single crystal 2 in the crystal longitudinal direction.

To achieve a desired crystal defect distribution (defect-free crystal) in a wafer surface in the CZ pulling of a silicon single crystal for 300 mm wafer, it is preferable to control the gap width (gap value) between the lower end of the heat-shield body 16 and liquid surface of the silicon melt 3 to 50 mm to 90 mm. When the gap value is thus set relatively large, the flow velocity of Ar gas from the center axis side of the pulling furnace to the outside thereof along the melt surface is likely to become lower than in the case where the gap value is small with the same Ar gas flow rate. When the additional doping is performed under such a condition, the probability that the silicon single crystal undergoes dislocation becomes high. In the present embodiment, in order to reduce the probability of the dislocation of the silicon single crystal, in-furnace conditions during the counter-doping process are changed as follows.

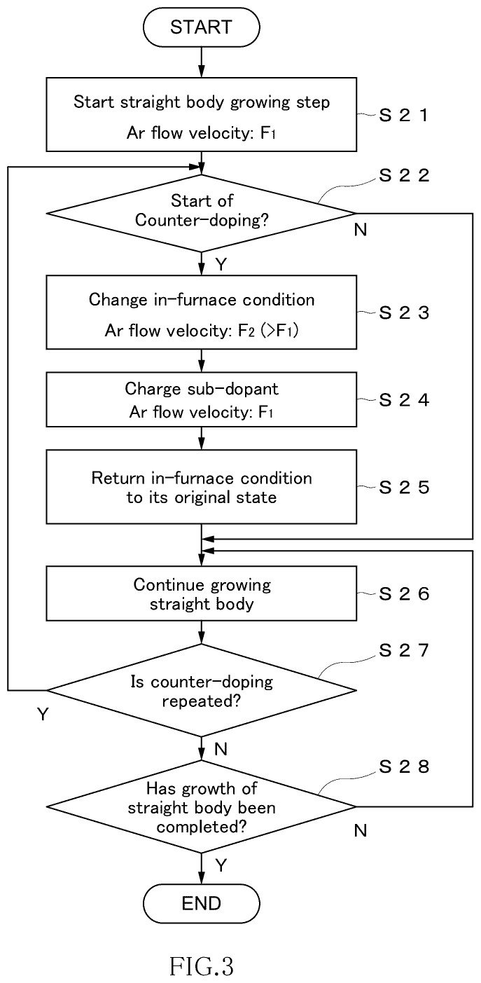

FIG. 3 is a flowchart for explaining the straight body growing step S16 including the counter-doping step (additional doping step).

As illustrated in FIG. 3, at the start of the straight body growing step S16, the flow velocity of the Ar gas (Ar flow velocity) flowing along the melt surface is set to a value suitable for the growth of the silicon single crystal (step S21). An Ar flow velocity F₁ (first flow velocity) required for the straight body growing step S16 is, for example, 0.3 m/s to 0.5 m/s.

The dopant concentration in the silicon single crystal increases as the crystal pulling advances, so that when the crystal pulling advances to a certain point in time, a resistivity value falls outside a desired resistivity range. Thus, when a timing requiring the counter-doping is required comes, the counter-doping is started (step S22Y, steps S23 to S25).

In the counter-doping, the dopant raw material 5 containing the sub-dopant is charged to the silicon melt 3 (step S24). The sub-dopant when an n-type silicon single crystal is pulled up is, for example, boron (B), aluminum (Al), gallium (Ga), or indium (In), and the sub-dopant when a p-type silicon single crystal is pulled up is, for example, phosphorus (P), arsenic (As), or antimony (Sb).

During a dopant charging period, the Ar flow velocity is changed to a value suitable for the counter-doping. An Ar flow velocity F₂ during the dopant charging period (second period) is set to a value (F₂>F₁) larger than the Ar flow velocity F₁ (first flow velocity) during a crystal pulling period (first period). The dopant charging period refers to a period during which the dopant raw material 5 is actually charged in a narrow sense; however, in a broad sense, it refers to a period required until the dopant charged to the silicon melt is completely dissolved to eliminate the problem of dislocation.

The Ar flow velocity F₂ during the dopant charging period is preferably 0.75 m/s to 1.1 m/s. When the Ar flow velocity is lower than 0.75 m/s, the charged dopant is carried to the silicon single crystal by melt convection, which may cause dislocation of the single crystal. On the other hand, when the Ar flow velocity is higher than 1.1 m/s, the fall position of the dopant becomes unstable due to, e.g., the occurrence of turbulence, with the result that the dopant falls near the silicon single crystal, which may cause dislocation of the single crystal. When the Ar flow velocity F₂ is 0.75 m/s or more and 1.1 m/s or less, it is possible to prevent dislocation of the silicon single crystal due to the sub-dopant being taken into the single crystal in an unmelted state.

The Ar flow velocity can be controlled by adjustment of at least one of the flow rate of the Ar gas to be fed into the pulling furnace and in-furnace pressure of the pulling furnace. An increase in the flow rate of the Ar gas increases the Ar flow velocity, and a reduction in the Ar flow rate reduces the Ar flow velocity. An increase in the in-furnace pressure reduces the Ar flow velocity, and a reduction in the in-furnace pressure increases the Ar flow velocity. The Ar flow velocity also changes depending on the gap value, so that the gap value can be used as an operational factor for the Ar flow velocity. Specifically, an increase in the gap value reduces the Ar flow velocity, and a reduction in the gap value increases the Ar flow velocity.

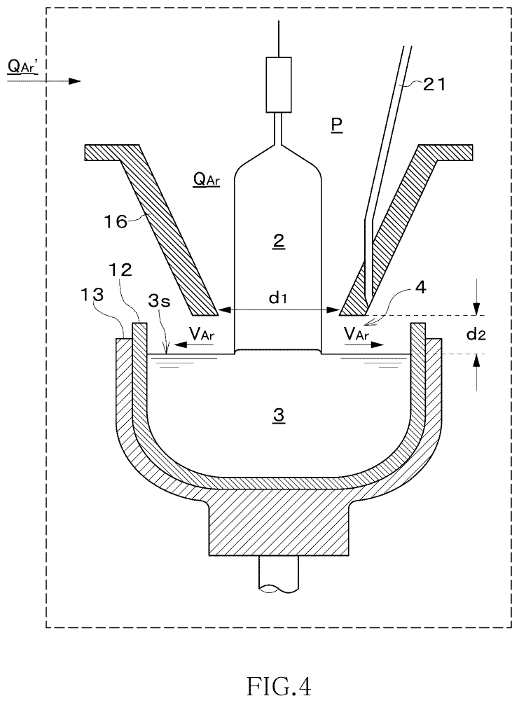

FIG. 4 is a view for explaining a method of calculating the Ar flow velocity.

The flow velocity of the Ar gas flowing in the vicinity of the melt surface 3s of the silicon melt 3 can be calculated as the average flow velocity of the Ar gas passing between the lower end of the heat-shield body 16 and the melt surface 3s. When the Ar flow velocity is V_{Ar} (m/s), the Ar flow rate in the pulling furnace is Q_{Ar} (mm³/s), and the sectional area of a gap 4 between the heat-shield body 16 and melt surface 3s is S (mm²), V_{Ar} can be calculated using the following expression:

$${V}_{Ar} = {Q}_{Ar} \times 1 {0}^{- 3} / S$$

The Ar flow rate Q_{Ar} in the pulling furnace can be calculated as follows from an Ar flow rate Q_{Ar}′ (mm³/s) before the Ar gas flows into the pulling furnace and an in-furnace pressure P (Torr):

$${Q}_{Ar} = {Q}_{Ar}^{′} \times 760 / P$$

The sectional area S between the heat-shield body 16 and the melt surface 3s can be calculated as follows from an aperture diameter d₁ (mm) and a distance (gap value) d₂ (mm) between the heat-shield body 16 and the melt surface 3s:

$$S = {d}_{1} \times π \times {d}_{2}$$

The Ar flow rate Q_{Ar}′ before the Ar gas flows into the pulling furnace is a converted flow rate under room temperature and atmospheric pressure and is controlled by the mass flow controller 32. When another gas is mixed with the Ar gas, the sum of the converted flow rate of the Ar gas and that of another gas are regarded as the Ar flow rate Q_{Ar}′. Examples of another gas include nitrogen gas and hydrogen gas. Thus, the flow velocity of the Ar gas flowing in the vicinity of the melt surface can be calculated from the Ar flow rate in the pulling furnace, in-furnace pressure, and dimension of the in-furnace structure.

In FIG. 4, the lower end surface of the heat-shield body 16 is horizontal, so that the gap value d₂ is the same at any position in the range from the inner peripheral end of the lower end portion of the heat-shield body 16 to the outer peripheral end thereof. However, when the lower end surface of the heat-shield body 16 is not horizontal, the gap value d₂ changes depending on the radial position of the heat-shield body 16, so that the calculation value of the Ar flow velocity also changes. When the inner diameter position at the lower end portion of the heat-shield body 16 is the lowermost end, from which the lower end surface of the heat-shield body 16 is inclined upward in the outer diameter direction, the Ar flow velocity may be evaluated at the inner diameter position, and it suffices that the Ar flow velocity thereat falls within a range of 0.75 m/s to 1.1 m/s. Further, when the lower end surface of the heat-shield body 16 is inclined downward in the outer diameter direction, the Ar flow velocity may be evaluated anywhere within a range from the inner diameter position at the lower end portion of the heat-shield body 16 to the lowermost end position on the outer diameter side thereof. In this case, in the calculation of the Ar flow velocity V_{Ar} described above, the aperture diameter d₁ (mm) of the heat-shield body 16 may be replaced with twice the radial distance from the center axis of the heat-shield body 16 to the Ar flow velocity evaluation position. At any rate, the Ar velocity V_{Ar} needs to be obtained at a position inside (close to the crystal side) of the dopant charging position in the radial direction of the heat-shield body 16.

As illustrated in FIG. 3, after completion of the counter-doping, the value of the Ar flow velocity is returned to F₁ during the crystal pulling period (first period) before the counter-doping step, and growth of the straight body is continued (steps S25 and S26).

The counter-doping step is performed repeatedly in accordance with a required crystal length (step S27Y, step S22Y, and steps S23 to S25). Even after completion of the counter-doping, growth of the straight body is continued, and when a timing requiring the counter-doping comes again, the counter-doping is started. The number of repetition times of the counter-doping is determined ahead of time, and the counter-doping is performed repeatedly until the number of repetition times reaches the specified value. Every time during the counter-doping, the Ar flow velocity is changed to a value (F₂) suitable for the counter-doping. Thus, a silicon single crystal having a desired length is pulled while the counter-doping is performed the specified number of times, whereby it is possible to increase the yield of silicon single crystals whose change in resistivity in the pulling axis direction is small.

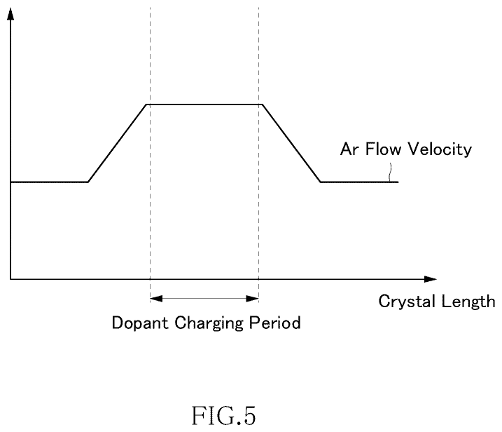

FIG. 5 is a graph illustrating the relation between the dopant charging period and Ar flow velocity.

As illustrated in FIG. 5, the Ar flow velocity is increased during the dopant charging period. Specifically, for example, the Ar flow velocity during the pulling period (first period) during which the dopant is not charged is set to 0.3 m/s to 0.5 m/s, and that during the dopant charging period (second period) is set to 0.75 m/s to 1.1 m/s.

The in-furnace pressure during the dopant charging period is preferably in the range of 10 Torr to 30 Torr. This is because when the in-furnace pressure during the dopant charging period exceeds 30 Torr, the probability that the silicon single crystal undergoes dislocation becomes high. This may be because the Ar flow velocity has distribution in the vicinity of the silicon melt surface, and the Ar flow velocity in an area extremely close to the silicon melt is reduced. The in-furnace pressure in the pulling period (first period) other than the counter-doping step may be the same as or different from the in-furnace pressure during the dopant charging period. Therefore, it is possible to set the in-furnace pressure during the pulling period (first period) other than the counter-doping step to 35 Torr to 45 Torr, for example.

When the flow velocity of the Ar gas flowing outward from the center side of the chamber 10 along the melt surface is increased, it is possible to prevent an unmelt dopant floating around the melt surface from being brought close to the solid-liquid interface between the silicon single crystal 2 and the silicon melt 3. This in turn can prevent dislocation of the silicon single crystal due to taking of the dopant into the solid-liquid interface between the silicon single crystal 2 and silicon melt 3.

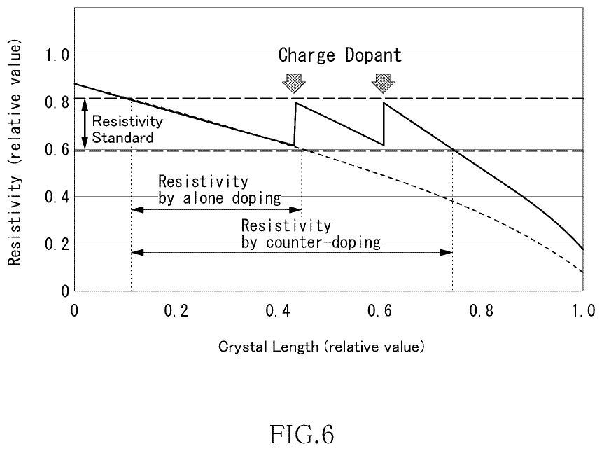

FIG. 6 is a graph illustrating a change in resistivity in the silicon single crystal when the counter-doping is performed two times. In this graph, the horizontal axis represents a crystal length (relative value when the total length of the straight body is 1), and the vertical axis represents a resistivity (relative value).

As illustrated in FIG. 6, in the case of a silicon single crystal doped with phosphorus alone as a main-dopant, the resistivity of the silicon single crystal is highest at the start of pulling and only gradually decreases as the pulling advances. Thus, when the crystal length exceeds about 0.44, the resistivity deviates from the standard.

However, by performing the first counter-doping at a position where the crystal length is about 0.44 and the second counter-doping at a position where the crystal length is 0.63, it is possible to make as long as possible the length of the single crystal at which the resistivity falls within the standard.

As described above, the manufacturing method for a silicon single crystal according to the present embodiment includes charging, to a silicon melt, a sub-dopant of the silicon single crystal having a conductivity type opposite to that of a main-dopant thereof during the silicon single crystal pulling, and the Ar flow velocity during the sub-dopant charging period is made higher than that during the sub-dopant non-charging period, whereby it is possible to prevent dislocation of the single crystal.

While the preferred embodiment of the present invention have been described, the present invention is not limited to the above embodiment, and various modifications may be made within the scope of the present invention, and all such modifications are included in the present invention.

For example, in the above embodiment, the counter-doping of adding a sub-dopant having a conductivity type opposite to that of a main-dopant is performed during the silicon single crystal pulling; however, the present invention is not limited to the counter-doping but may be applied to the additional doping that adds a sub-dopant having the same conductivity type as that of a main-dopant. Further, in the above embodiment, the CZ pulling in which a magnetic field is not applied to the silicon melt upon pulling of the silicon single crystal has been taken as an example; however, the present invention may be applied to a so-called MCZ method of pulling the silicon single crystal while applying a magnetic field to the silicon melt.

Further, in the above embodiment, the Ar flow velocity F₂ during the sub-dopant charging period is made higher than the Ar flow velocity F₁ before charging of the sub-dopant to be set to 0.75 m/s to 1.1 m/s; however, in the present invention, it is only necessary to change the Ar flow velocity F₁ before charging of the dopant to 0.75 m/s to 1.1 m/s during the dopant charging period as the Ar flow velocity F₂. That is, the Ar flow velocity F₂ during the sub-dopant charging period may be made lower than the Ar flow velocity F₁ before charging of the sub-dopant.

### Example

During the CZ pulling process of a silicon single crystal for a wafer having a diameter of 300 mm, influence that the Ar flow velocity during the counter-doping has on silicon single crystal pulling results was evaluated. In the evaluation test, the counter-doping was performed two times in the middle of the straight body growing step of an n-type silicon single crystal using phosphorus (P) as a main-dopant. During the silicon single crystal pulling step other than the counter-doping, the Ar flow velocity was maintained at 0.3 m/s to 0.5 m/s. On the other hand, during the counter-doping in the counter-doping step, the Ar flow velocity was changed to values different from (or the same value as) the Ar flow velocity before the counter-doping as illustrated in Table 1, and the change state of the Ar flow velocity was maintained for 15 minutes. After that, the Ar flow velocity was returned to that before the change (see FIG. 5). It took 20 minutes to change (increase and decrease) the Ar flow velocity. The sub-dopant was charged during the 15-minute period during which the changed Ar flow velocity was maintained.

Further, in the evaluation test, a case where different gap values had been applied to the same Ar flow velocity was also evaluated. The gap values applied were the following seven values: 40 mm, 50 mm, 60 mm, 70 mm, 80 mm, 90 mm, and 100 mm. The results of the Ar flow velocity evaluation test are shown in Table 1.

TABLE 1

| Ar flow | | | | | | | |
|---|---|---|---|---|---|---|---|
| velocity | Gap value (mm) | | | | | | |
| (m/s) | 40 | 50 | 60 | 70 | 80 | 90 | 100 |
| 0.20 | x | x | x | x | x | x | x |
| 0.30 | x | x | x | x | x | x | x |
| 0.40 | x | x | x | x | x | x | x |
| 0.50 | x | x | x | x | x | x | x |
| 0.60 | x | x | x | x | x | x | x |
| 0.70 | x | x | x | x | x | x | x |
| 0.75 | ∘ | ∘ | ∘ | ∘ | ∘ | ∘ | ∘ |
| 0.80 | ∘ | ∘ | ∘ | ∘ | ∘ | ∘ | ∘ |
| 0.90 | ∘ | ∘ | ∘ | ∘ | ∘ | ∘ | ∘ |
| 1.00 | ∘ | ∘ | ∘ | ∘ | ∘ | ∘ | ∘ |
| 1.10 | ∘ | ∘ | ∘ | ∘ | ∘ | ∘ | ∘ |
| 1.15 | x | x | x | x | x | x | x |
| 1.2 | x | x | x | x | x | x | x |
| 1.3 | x | x | x | x | x | x | x |
| 1.4 | x | x | x | x | x | x | x |
| 1.5 | x | x | x | x | x | x | x |
| 2.0 | x | x | x | x | x | x | x |
| 3.0 | x | x | x | x | x | x | x |
| 4.0 | x | x | x | x | x | x | x |

∘: Absence of dislocation
x: Presence of dislocation

As is clear from Table 1, when the Ar flow velocity was 0.20 m/s to 0.70 m/s, the silicon single crystal underwent dislocation due to the influence of the sub-dopant added during the counter-doping. Also when the Ar flow velocity was relatively as high as 1.15 m/s to 4.0 m/s, the silicon single crystal underwent dislocation due to the influence of the sub-dopant added during the counter-doping. However, when the Ar flow velocity was 0.75 m/s to 1.10 m/s, dislocation of the silicon single crystal did not occur. The same results were obtained even in the case where the gap value was changed within a range of 10 mm to 100 mm.

Then, the silicon single crystal thus obtained was checked for defects, including infrared scattering band defects such as COP (Crystal Originated Particle) and OSF (Oxidation-induced Stacking Fault), and dislocation clusters such as LD (interstitial-type Large Dislocation). The results are shown in Table 2.

TABLE 2

| | Gap Value (mm) | | | | | | |
|---|---|---|---|---|---|---|---|
| | 40 | 50 | 60 | 70 | 80 | 90 | 100 |
| Defect-free | x | ∘ | ∘ | ∘ | ∘ | ∘ | x |
| crystal | | | | | | | |

∘: Absence of defect
x: Presence of defect

As is clear from Table 2, silicon single crystals pulled while the gap value was being controlled between 50 mm and 90 mm were defect-free crystals, but silicon single crystals pulled while the gap value was being controlled between 40 mm and 100 mm had defects and thus were not defect-free crystals.

### DESCRIPTION OF REFERENCE NUMERALS

1 Single crystal manufacturing apparatus
2 Silicon single crystal
3 Silicon melt
3s Melt surface
4 Gap
5 Dopant (Sub-dopant)
10 Chamber
10a Main chamber
10b Top chamber
10c Pull chamber
10d Gas inlet port
10e Gas exhaust port
11 Heat insulating material
12 Quartz crucible
13 Susceptor
14 Shaft
15 Heater
16 Heat-shield body
17 Pulling wire
18 Wire winding mechanism
20 Dopant feeding device
21 Dopant feeding tube
22 Dopant hopper
23 Seal cap
30 Controller
31 Gas supply source
32 Mass flow controller
33 Vacuum pump
S11 Material filling step
S12 Melting step
S13 Dipping step
S14 Necking step
S15 Shoulder growing step
S16 Straight body growing step
S17 Tail growing step

1. A manufacturing method of a silicon single crystal comprising:
a melting step of producing a silicon melt containing a main-dopant in a pulling furnace; and
a crystal pulling step of pulling a silicon single crystal from the silicon melt while feeding Ar gas into the pulling furnace; wherein
the crystal pulling step includes at least one additional doping step of charging a sub-dopant to the silicon melt, and
the additional doping step regulates a flow velocity of the Ar gas passing through a gap between a lower end of a heat-shield body installed above the silicon melt so as to surround the silicon single crystal pulled from the silicon melt and a liquid surface of the silicon melt to 0.75 m/s to 1.1 m/s.

2. The manufacturing method of a silicon single crystal according to claim 1, wherein
a width of the gap is controlled to 50 mm to 90 mm in the crystal pulling step.

3. The manufacturing method of a silicon single crystal according to claim 1, wherein
the additional doping step regulates the flow velocity of the Ar gas by controlling at least one of the flow rate of the Ar gas to be fed into the pulling furnace and an internal pressure of the pulling furnace.

4. The manufacturing method of a silicon single crystal according to claim 1, wherein
the additional doping step controls an internal pressure of the pulling furnace to 10 Torr to 30 Torr.

5. The manufacturing method of a silicon single crystal according to claim 1, wherein
the crystal pulling step returns the flow velocity of the Ar gas after completion of the additional doping step to the flow velocity of the Ar gas before the start of the additional doping step.

6. The manufacturing method of a silicon single crystal according to claim 2, wherein
the additional doping step regulates the flow velocity of the Ar gas by controlling at least one of the flow rate of the Ar gas to be fed into the pulling furnace and an internal pressure of the pulling furnace.

7. The manufacturing method of a silicon single crystal according to claim 2, wherein
the additional doping step controls an internal pressure of the pulling furnace to 10 Torr to 30 Torr.

8. The manufacturing method of a silicon single crystal according to claim 2, wherein
the crystal pulling step returns the flow velocity of the Ar gas after completion of the additional doping step to the flow velocity of the Ar gas before the start of the additional doping step.
